(19) United States
(12) Patent Application Publication
(10) Pub. No.: US 2018/0097134 A1
(43) Pub. Date: Apr. 5, 2018

(54) LIGHTWEIGHT SOLAR MODULE BUILDING MATERIALS SET AND SOUND INSULATION WALL USING THE SET

(71) Applicant: GIXIA GROUP Co., Jhubei City (TW)

(72) Inventors: Jung-Ya Hsieh, Jhubei City (TW); Yung-Fu Lin, Jhubei City (TW); Yuan-Hsin Chang, Jhubei City (TW); Shih-Yuan Lin, Taoyuan City (TW)

(73) Assignee: GIXIA GROUP Co.

(21) Appl. No.: 15/438,962

(22) Filed: Feb. 22, 2017

(30) Foreign Application Priority Data
Oct. 5, 2016 (TW) 105132200

(51) Int. Cl. H01L 31/048; H02S 20/23; B06B 3/02; G10K 11/172

(52) U.S. Cl. CPC H01L 31/048; G10K 11/172; B06B 3/02; H02S 20/23

(57) ABSTRACT

A lightweight solar module building materials set includes a solar module, a perforated plate defining multiple perforations, and a support assembly which is essentially composed of a supportive plate and a honeycomb structure and can support the solar module and the perforated plate. The perforated plate, the honeycomb structure, and the supportive plate define multiple sound absorption compartments. Sound waves can enter the sound absorption compartments via the perforations of the perforated plate. The solar module includes a solar cell body, which is protected by a flexible transparent protective layer and supported by the support assembly, to conduct photoelectric conversion. The solar module building materials set can be mounted on an affixing means to construct a sound insulation wall, which can generate solar power and absorb sound waves. As such, the ratio of green energy supply and the comfort of life can be increased.

### FIELD OF THE INVENTION

The present invention relates to a lightweight solar module building materials set and a sound insulation wall using the solar module building materials set.

### BACKGROUND OF THE INVENTION

Green energy is known as clean energy, such as wind power, hydraulic power, and solar power, which are usually converted to electricity. Due to the popularity of solar technology and the increase of the photoelectric conversion efficiency, in sunny countries, there are many buildings or fields having been installed with solar panels. There are devices, such as the electronic indication boards located on buildings or roads, are supplied with the electrical power generated from solar panels.

FIG. 1 shows a conventional solar panel, which is composed of a glass substrate 91 (top layer), a first EVA adhesive layer 92, a solar cell body 93, a second EVA adhesive layer 92, a back board 94 (lower layer). In assembling the parts, the two adhesive layers 92 can be heated, and the glass substrate 91 and the back board 94 can be pressed towards the solar cell body 93, so that solar cell body 93 can be attached between the glass substrate 91 and the back board 94. The glass substrate 91 can protect the solar cell body 93 from being damaged and allows sunlight to pass therethrough to be absorbed by the solar cell body 93. Also, the back board 94 can protect the solar cell body 93 and can collaborate with the glass substrate 91 to support the entire structure of the solar panel and to ensure the structural strength of the solar panel.

Since solar cell is a product manufactured with a semiconductor process, the solar cell body of the conventional solar panel is very thin. As a result, the conventional solar cell body is easy to break or prone to microcracks upon an impact, thus failing to smoothly generate electricity. For overcoming the disadvantage, the glass substrate of the conventional solar panel has to be thickened to ensure the protection of the solar body cell. According to the current technology, the dimension of a conventional solar panel may reach 160 cm in length and 100 cm in width, and the weight of the conventional solar panel may reach 20 kilograms. If a building is installed at its roof with solar panels which occupies more than 100 square meters, the building will be subjected to additional load, which may amount to dozens of tons, and thus the structural strength of the building may be affected significantly.

On the other hand, for increasing the capacity of solar power generation or the ratio of green energy to total energy required for a nation, there is a demand of large areas of land to be installed with solar panels. Furthermore, if solar panels are installed in remote areas, there will be additional cost of electrical transmission and distribution lines; in addition, this cost would incur the cost of repair and maintenance. In developed towns, the land cost is too high to be available. Thus, installing solar panels on public constructions is a cost-effective way to increase the ratio of solar power supply. The public constructions, which do not incur land acquisition fees and can facilitate repair and maintenance, include the existing sound insulation walls at two sides of highways, elevated railways and MRT systems, two fences of bridges, and so on.

However, if the existing sound insulation walls located at two sides of a highway, an elevated road or a bridge are installed with a lot of conventional solar panels, the sound insulation walls or the bridge will experience additional load, which may amount to several tons, and thus the life spans of the sound insulation walls or the bridge may be shortened. Besides, the solar panels mounted on the existing sound insulation walls may be hit by a high-speed vehicle that is out of control, the broken glass from the conventional solar panels may damage the persons nearby. Thus, conventional solar panels are unsuitable to be mounted at highways, elevated roads or bridges.

In view of the foregoing, there is a need to develop an improved solar module structure, which has an increased strength and a decreased weight, and is structured to absorb sound waves, to increase the ratio of green energy supply and to reduce environmental noise.

### SUMMARY OF THE INVENTION

One object of the present invention is to provide a lightweight solar module building materials set, which can generate green power to save energy and to reduce carbon, and can absorb sound waves to reduce environmental noise level.

Another object of the present invention is to provide a lightweight solar module building materials set, which is provided with flexible transparent protective layer and a support assembly which is light and tough, so that the weight of the solar module building materials set can be reduced significantly, and the life span and structural strength of a construction, on which the solar module building materials set is mounted, can be reduced significantly.

A further object of the present invention is to provide a lightweight solar module building materials set, which does not contain glass and is high in ductility and thus is difficult to break upon a strong collision, so that it can be safely used to construct a sound insulation wall for a highway.

A still further object of the present invention is to provide a sound insulation wall using a lightweight solar module building materials set, which can be constructed to not only absorb sound waves for noise reduction but also to generate solar power for the purpose of energy saving and carbon reduction.

A yet still further object of the present invention is to provide a sound insulation wall using a lightweight solar module building materials set, wherein the flexible transparent protective layer of the solar module can be slightly colored, and furthermore, large area installation of solar modules can form a work of art to beautify a city.

The lightweight solar module building materials set may comprise a support assembly, at least one perforated plate, and at least one solar module. The support assembly includes a honeycomb structure and at least one supportive plate, wherein the honeycomb structure has multiple units each defining an inner space extending from a first side of the honeycomb structure to a second side of the honeycomb structure; the supportive plate is provided at the first side of the honeycomb structure. The perforated plate, which defines multiple perforations, is provided at the second side of the honeycomb structure, thus defining multiple sound absorption compartments between the honeycomb structure, the supportive plate and the perforated plate. The perforations of the perforated plate respectively communicate with the sound absorption compartments, so that sound waves can enter the sound absorption compartments via the perforations. The solar module includes at least one solar cell body, a flexible transparent protective layer, and at least one attachment part, wherein the protective layer can protect the solar cell body, the attachment part can attach the solar cell body and the protective layer to one side of the supportive plate that is away from the honeycomb structure, so that the solar cell body is disposed between the flexible transparent protective layer and the supportive plate.

Furthermore, the lightweight solar module building materials set can be mounted on an affixing means to construct a sound insulation wall on a construction. The sound insulation wall includes at least one solar module building materials set and at least one affixing means.

Due to the flexible transparent protective layer being made of resin, and the honeycomb structure being made of aluminum or titanium alloy, which is high in ductility, the total weight of the sound insulation wall can be reduced and the components of the sound insulation wall can be transported and assembled easily. Furthermore, the load of the sound insulation wall on a construction can be reduced significantly, and the damages caused by an impact on the sound insulation wall can be reduced significantly, thus increasing the safety of the sound insulation wall. In addition to the solar module capable of generating electricity to achieve the purpose of energy saving and carbon reduction, the sound absorption compartment defined between the perforated plate, the honeycomb structure, and the supportive plate can absorb sound waves effectively to reduce environmental noise level, thus increasing the comfort of life.

### BRIEF DESCRIPTION OF THE DRAWINGS

The foregoing and other features and advantages of illustrated embodiments of the present invention will be more readily apparent from the following detailed description, which proceeds with reference to the accompanying drawings.

FIG. 1 shows an exploded view of a conventional solar panel of a prior art.

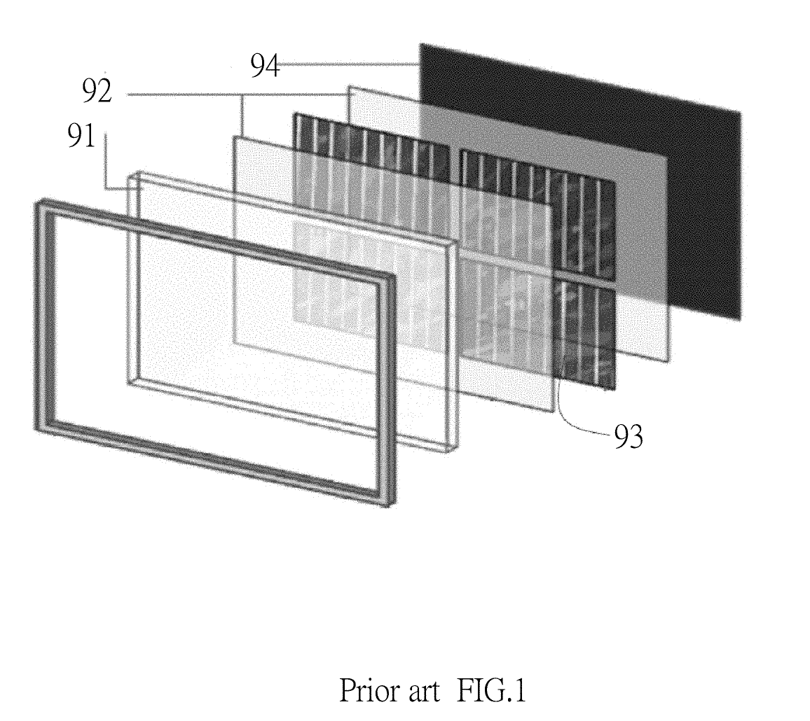

FIG. 2 shows a partially 3-dimensional view of a sound insulation wall according to a first embodiment of the present invention, wherein the sound insulation wall is installed at a roof of a building.

FIG. 3 shows an exploded view of a solar module building materials set used to construct the sound insulation wall of the first embodiment of the present invention.

FIG. 4 shows a 3-dimensional view of the sound absorbing structure of the sound insulation wall of the first embodiment of the present invention, wherein multiple sound absorption compartments are shown.

FIG. 5 shows a partially 3-dimensional view of a sound insulation wall according to a second embodiment of the present invention, wherein the sound insulation wall is installed at one side of a highway.

FIG. 6 shows an exploded view of a solar module building materials set used to construct the sound insulation wall of the second embodiment of the present invention.

FIG. 7 shows an exploded view of the sound absorbing structure of the solar module building materials set shown in FIG. 6.

FIG. 8 shows a partially 3-dimensional view of a sound insulation wall according to a third embodiment of the present invention.

### DETAILED DESCRIPTION OF THE ILLUSTRATED EMBODIMENTS

The foregoing and other technical contents, features and advantages of the present invention will be illustrated in detail by way of exemplary embodiments with reference to the accompanying drawings. In the exemplary embodiments, same elements will be indicated by similar numerals or labels.

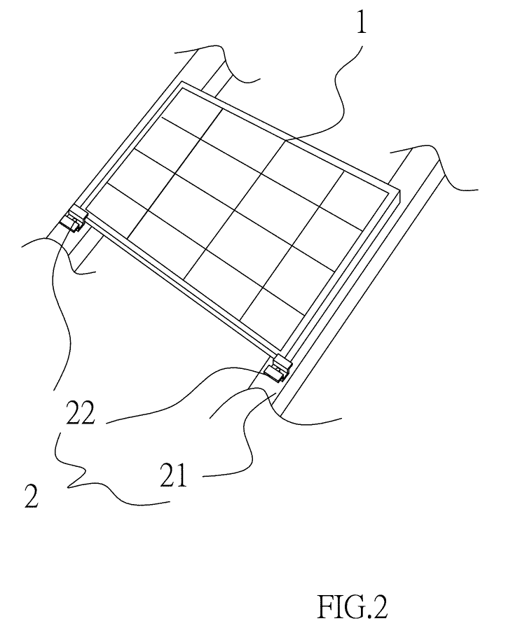

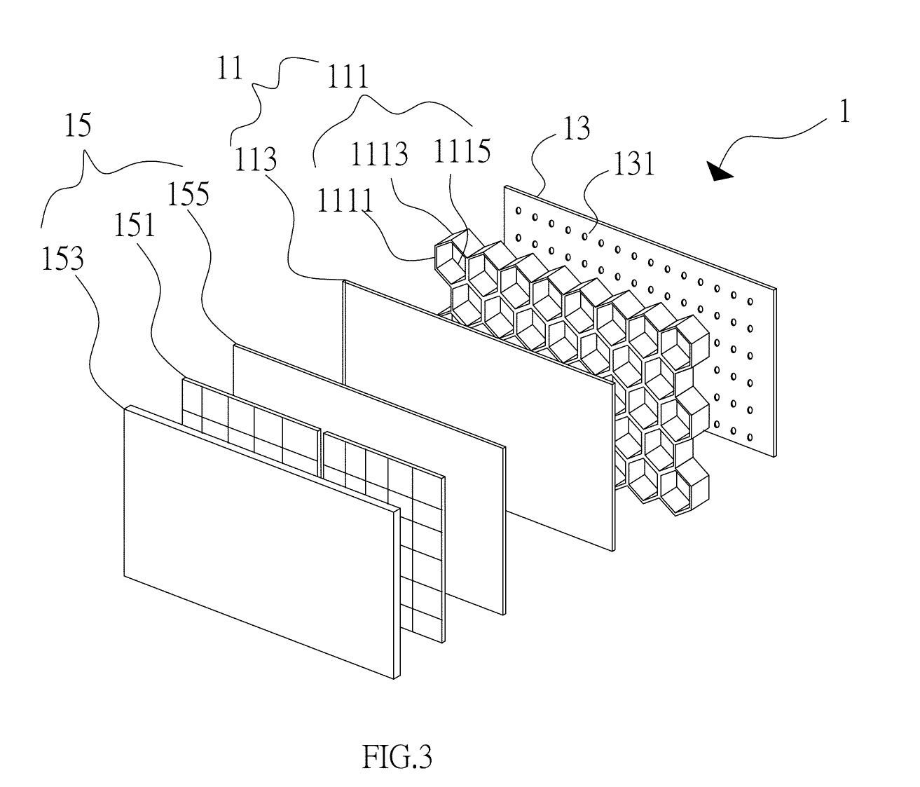

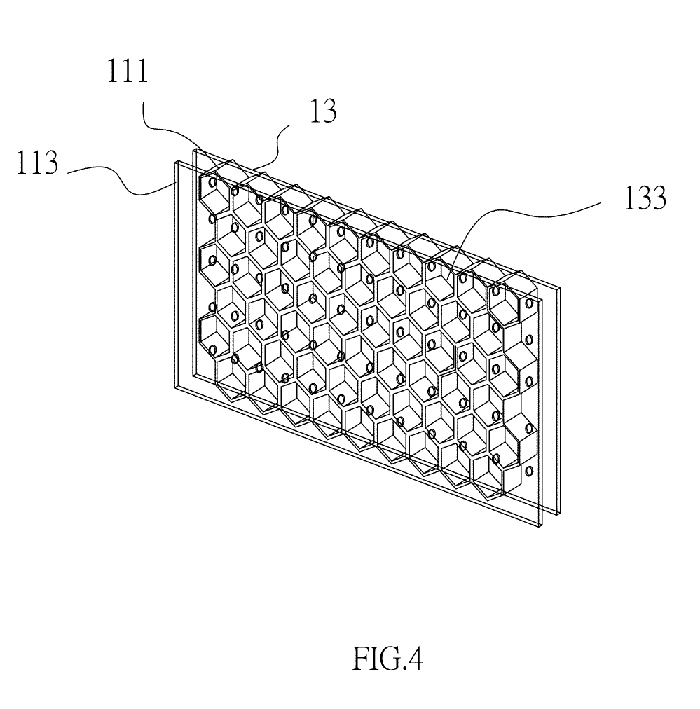

FIGS. 2 through 4 show a first embodiment of the present invention, which is concerned with a sound insulation wall mounted on a roof of a building by using a lightweight solar module building materials set of the present invention. For easy of illustration, only one solar module building materials set 1 and an affixing means 2 for the building materials set are shown in FIG. 2.

The solar module building materials set 1 generally includes a support assembly 11, a perforated plate 13 defining multiple perforations 131, and a solar module 15. The support assembly 11 is composed of a honeycomb structure 111 and a supportive plate 113, both of which are used to support the entire structure of the sound insulation wall and can achieve the effect of reducing the total weight of the sound insulation wall. The honeycomb structure 111 and the supportive plate 113 can be made of an aluminum alloy. The honeycomb structure 111 contains multiple units, each of which defines an inner space 1115 extending from a first side 1111 of the honeycomb structure to a second side 1113 of the honeycomb structure (opposite to the first side). The inner space 1115 of each unit of the honeycomb structure can be in the form of a hexagonal hole. The support assembly 11 can maintain three-dimensional support strength while reduce the total weight of the sound insulation wall. The supportive plate 113 can enhance the connection between the solar module 15 and the support assembly 11.

On the other hand, the perforated plate 13 is provided at the second side 1113 of the honeycomb structure 111, so that the honeycomb structure 111, the supportive plate 113 and the perforated plate 13 define multiple sound absorption compartments 133 therebetween. In installing a sound insulation wall, the perforations 131 of the perforated plate 13, which respectively communicate with the sound absorption compartments 133, can face towards a roof of a house. Thus, sound waves in the house may enter the sound absorption compartments 133 via the perforations 131 of the perforated plate 13, and thus most of the sound waves can be confined therein and absorbed by the honeycomb structure 111, the supportive plate 113, and the perforated plate 13, thus reducing the noise level. After repeated tests, it is found that the sound insulation wall can achieve a better effect of noise reduction when the perforated plate 13 has a perforation ratio not more than 3%, and the diameter of each perforation is not more than 1 mm.

The solar module 15 is located at one side of the supportive plate 113 that is away from the perforated plate 13 and can face towards the sun for receiving solar energy. The solar module 15 is essentially composed of a solar cell body 151, a flexible transparent protective layer 153, and an attachment part 155, wherein the solar cell body 151 can be attached to the supportive plate 113 by the attachment part 155. One example of the attachment part 155 is an EVA (ethylene-vinyl acetate) adhesive layer, which can be melted by heat. The solar cell body 151 is provided at a solar receiving surface thereof with the flexible transparent protective layer 153 to protect the solar cell body 151 from damages of foreign matter. One example of the protective layer is a silicone layer with a transmission coefficient more than 95%. As compared with conventional solar panels, the solar module of the present invention has higher conversion efficiency, and the protective layer 153 can be made thinner and lighter, thus reducing the weight of the solar module.

In this embodiment, the affixing means 2 may include plural pairs of metal rails 21, which are parallel to each other, and plural pairs of restriction members 22. For simplicity, only one pair of metal rails 21 and one pair of restriction members 22 are shown in FIG. 2. In installing a sound insulation wall, firstly, one pair of metal rails 21 can be affixed onto a roof of a cement construction by bolts, wherein the perforated plate 13 faces towards the roof of the construction. Next, the solar module building materials set 1 can be placed on the metal rails 21, and then two restriction members 22 can be located at two lower corners of the building materials set and fixed to the metal rails 21 by fasteners (not shown) so as to limit movement of the building materials set.

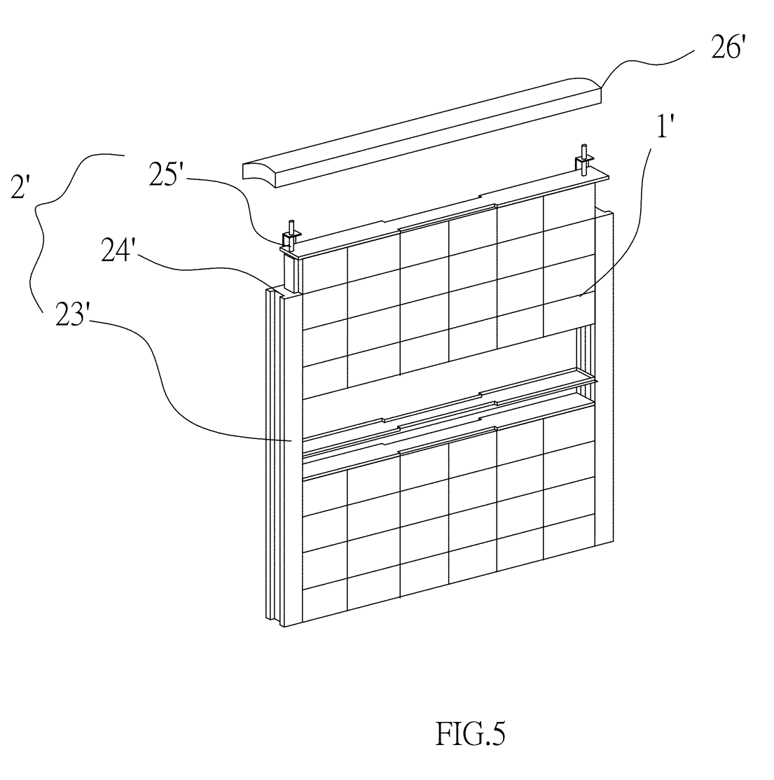

For increasing the ratio of green energy supply, the solar module building materials set of the present invention can be installed at a highway, wherein the sound insulation walls using the building materials set of the present invention can replace the existing sound insulation walls of the highway. Referring to FIGS. 5 through 7, a second embodiment of the present invention is shown. In this embodiment, the solar module building materials set 1′ is composed of two building material groups, each of which includes a perforated plate 13′, a support assembly 11′, and a solar module 15′. The components of the two building material groups are arranged symmetrically about a central line therebetween. More specifically, the two material groups are arranged back to back, wherein the solar cell module 15′ of each group is located at the outer side of the associated group, and the perforated plate 13′ of each group is located at the inner side of the associated group; thus, the two perforated plates 13′ can face each other.

The support assembly 11′ includes a honeycomb structure 111′, which can reduce the weight of the support assembly. The honeycomb structure 111′ contains multiple units, which can be arranged in a periodic and regular pattern. Each unit defines an inner space 1115′, which can be in the form of a polygon through hole. In this embodiment, for increasing the structural strength to withstand the wind pressure across a highway, the inner space 1115′ is in the form of a trapezoidal hole and has a different size. Of course, the units of the honeycomb structure 111′ can be configured to have other shapes, provided that the units are arranged in a periodic and regular pattern. Also, in this embodiment, a pair of safety through-holes 1117′ can be defined between two opposite sides (upper side and lower side) that are perpendicular to the first side 1111′ and the second side 1113′ of the honeycomb structure 111′.

Preferably, the support assembly 11′ and the perforated plate 13′ are made of titanium or aluminum alloy of high ductility; the flexible transparent protective layer is a silicone layer. Due to the protective layer containing resin and silicone, which allow the solar cell body 151′ to be firmly attached to the support assembly 11′, if the solar module 15′ is hit by a high-speed vehicle, damages caused by the hit can be significantly reduced compared with conventional solar panels which are covered with glass. The solar module building materials set 1′ of the present invention can be used to build sound insulation walls at two sides of a highway in place of conventional ones. In addition to reducing noise level, the sound insulation walls using the solar module building materials set of the present invention can supply green energy.

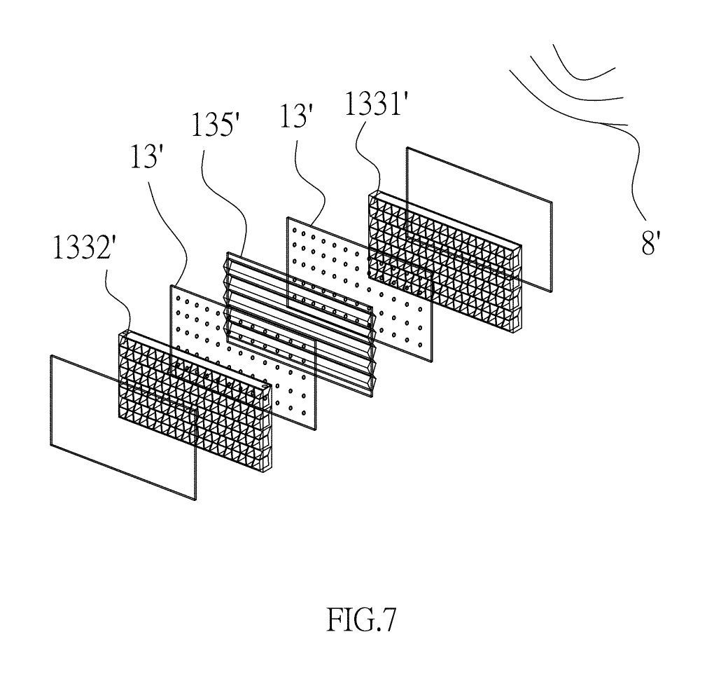

For a sound insulation wall using the solar module building materials set 1′ of the present invention, the sound waves 8′ generated from vehicles on the highway can reach the solar module 15′ thereof via air, where part of the sound waves can be reflected or absorbed by the solar module 15′, and part of the sound waves can pass through the solar module 15′ to enter the first sound absorption compartments 1331′, where part of the entered sound waves can be absorbed, and part of the entered sound waves can enter the second sound absorption compartments 1332′, where the second entered sound waves can be further absorbed. For increasing the effect of absorbing sound waves, as shown in FIG. 7, a sound absorbing member 135′, such as a piece of cotton, can be disposed between the two perforated plates 13′. Those skilled in the art may understand that the positions of the perforated plates 13′ can be adjusted to reduce the intersection of the perforations of the perforated plates 13′.

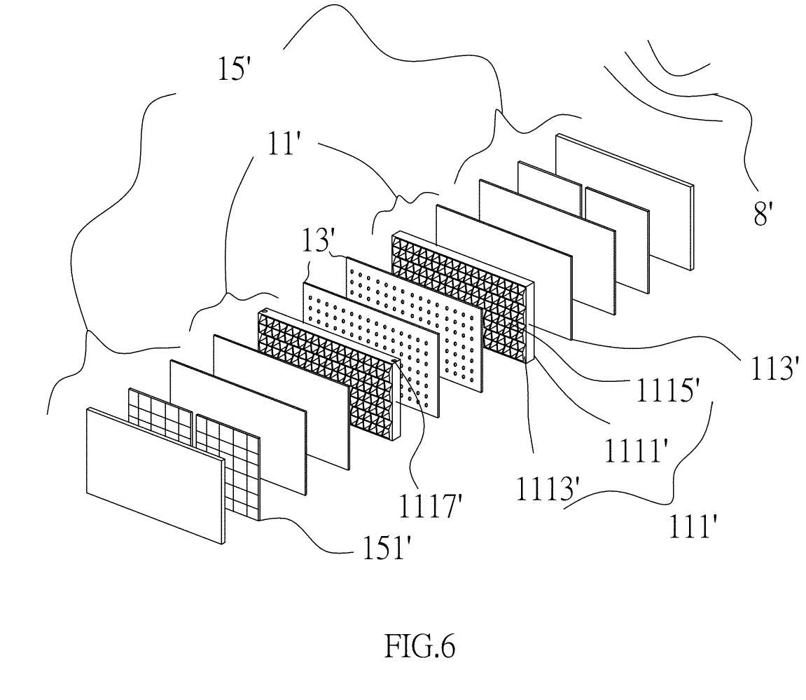

In installing sound insulation walls on the constructions at two sides of a highway, as shown in FIG. 5, the existing H-beams 23′ can be used as one means, indicated by reference numeral 2′, for affixing the solar module building materials set 1′ of the present invention to a construction. As shown, each H-beam 23′ defines two opposite engagement recesses 24′. In installation, firstly, a pair of H-beams 23′ can be fixed at the construction. Next, a solar module building materials set 1′ can be placed between the H-beams 23′ from above. Finally, an elongated cap 26′ can be mounted on top of the H-beams 23′ and the solar module building materials set 1′. In addition, for increasing the safety of the sound insulation wall, a pair of anti-off cables 25′ can be inserted through two safety through-hoes 1117′ (see FIG. 6), wherein one end of each cable 25′ can be attached to the bottom of one corresponding H-beam, while the other end of each cable 25′ can be attached to the elongated cap 6′. Those skilled in the art may understand that the solar module building materials set 1′ of the present invention can be provided with two protection clamps (not shown), each of which defines a through hole to allow one of the cables 25′ to insert therethrough.

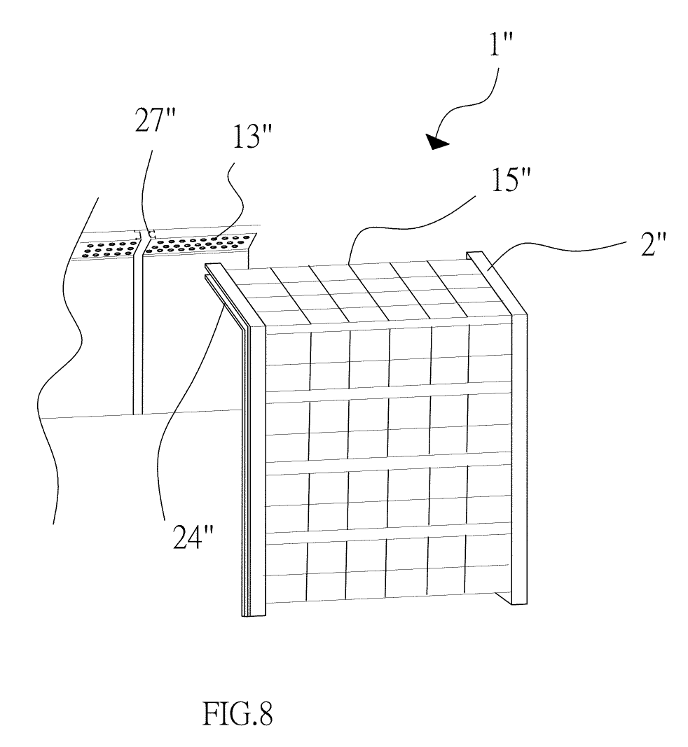

For increasing the performance of a sound insulation wall at a highway, the top portion of the sound insulation wall can be curved inwardly of the highway. Under this circumstance, since the inner side of the top portion of the sound insulation wall is uneasy to receive sunlight, the top portion of the sound insulation wall can be constructed by a single-group building materials set. FIG. 8 shows a third embodiment of the present invention, wherein the solar module building materials set 1″ contains one solar module. Particularly, the engagement recess 24″ can be provided with a foolproof protrusion 27″ to allow the perforated plate 13″ of the building materials set 1″ to face towards the highway when installing the sound insulation wall, and to allow the solar module 15″ of the building materials set 1″ to face towards the sun, so that the sound waves generated from vehicles on the highway can be absorbed easily by the sound absorption compartments of the building materials set 1″, which face towards the highway, and the sun can shine on the solar module 15″ which is located at the outer side of the building materials set 1″. Of course, those skilled in the art may understand that the components of the building materials set 1″ of the present invention can be assembled in manners other than those of the above embodiments, and the building materials set can be fixed by other devices.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit and scope of the invention.

What is claimed is:

1. A lightweight solar module building materials set, comprising:
a support assembly including a honeycomb structure and at least one supportive plate, wherein the honeycomb structure has multiple units each defining an inner space extending from a first side of the honeycomb structure to a second side of the honeycomb structure; the supportive plate is provided at the first side of the honeycomb structure;
at least one perforated plate defining multiple perforations and provided at the second side of the honeycomb structure to define multiple sound absorption compartments between the honeycomb structure, the supportive plate and the perforated plate, the perforations of the perforated plate respectively communicating with the sound absorption compartments, wherein sound waves allow to enter the sound absorption compartments via the perforations; and
at least one solar module including at least one solar cell body, a flexible transparent protective layer, and at least one attachment part, the flexible transparent protective layer capable of protecting the solar cell body, the attachment part capable of attaching the solar cell body and the protective layer to one side of the supportive plate that is away from the honeycomb structure, so that the solar cell body is disposed between the flexible transparent protective layer and the supportive plate.

2. The lightweight solar module building materials set of claim 1, wherein the units of the honeycomb structure are arranged in a periodic and regular pattern.

3. The lightweight solar module building materials set of claim 2, wherein the inner space of each unit of the honeycomb structure is in the form of a polygonal hole.

4. The lightweight solar module building materials set of claim 1, wherein the flexible transparent protective layer is a silicone layer having a transmission coefficient more than 95%.

5. The lightweight solar module building materials set of claim 1, further comprising a sound absorbing member.

6. The lightweight solar module building materials set of claim 1, wherein the attachment part is an adhesive layer.

7. A sound insulation wall for a construction, comprising:
at least one solar module building materials set, including:
a support assembly including a honeycomb structure and at least one supportive plate, wherein the honeycomb structure has multiple units each defining an inner space extending from a first side of the honeycomb structure to a second side of the honeycomb structure; the supportive plate is provided at the first side of the honeycomb structure;
at least one perforated plate defining multiple perforations and provided at the second side of the honeycomb structure to define multiple sound absorption compartments between the honeycomb structure, the supportive plate and the perforated plate, the perforations of the honeycomb structure respectively communicating with the sound absorption compartments, wherein sound waves allow to enter the sound absorption compartments via the perforations; and
at least one solar module including at least one solar cell body, a flexible transparent protective layer, and at least one attachment part, the flexible transparent protective layer capable of protecting the solar cell body, the attachment part capable of attaching the solar cell body and the flexible transparent protective layer to one side of the supportive plate that is away from the honeycomb structure, so that the solar cell body is disposed between the flexible transparent protective layer and the supportive plate; and
means for affixing the solar module building materials set to the construction.

8. The sound insulation wall of claim 7, wherein the affixing means includes a pair of H-beams, each defining two opposite engagement recesses.

9. The sound insulation wall of claim 8, wherein each of the H-beams is provided with a foolproof protrusion in one of the engagement recesses.

10. The sound insulation wall of claim 7, wherein the honeycomb structure defines at least one pair of safety through-holes extending between two opposite sides which are perpendicular to the first side of the honeycomb structure.

11. The sound insulation wall of claim 10, wherein the affixing means includes a pair of anti-off cables capable of being inserted through the safety through-holes defined at the honeycomb structure.

12. The sound insulation wall of claim 7, wherein the affixing means includes a pair of metal rails each provided with at least one restriction member.
